(19) United States
(12) Patent Application Publication
(10) Pub. No.: US 2015/0012718 A1
(43) Pub. Date: Jan. 8, 2015

(54) SYSTEM FOR COMPENSATING FOR DYNAMIC SKEW IN MEMORY DEVICES

(71) Applicants: Atul Gupta, Noida (IN); Ajay Gaite, Najafgarh (IN)

(72) Inventors: Atul Gupta, Noida (IN); Ajay Gaite, Najafgarh (IN)

(21) Appl. No.: 13/935,554

(22) Filed: Jul. 4, 2013

(51) Int. Cl. G11C 7/22; G06F 1/08

(52) U.S. Cl. CPC G11C 7/22; G06F 1/08
USPC 711/167

(57) ABSTRACT

A memory device includes a memory array, a memory controller, data lines connecting the memory array and the memory controller, and a delay compensation module. The delay compensation module includes a delay line that provides delayed clock signals, a look-up table that stores a mapping between predefined data bit patterns and corresponding propagation delays for each data line, and delay compensation logic modules corresponding to the data lines. The delay compensation logic modules receive data bit patterns carried by the data lines, select propagation delays based on the data bit patterns and the look-up table data, and delay the bits carried by corresponding ones of the data lines based on delayed clock signals corresponding to the propagation delays.

### BACKGROUND OF THE INVENTION

The present invention relates generally to memory devices, and more particularly, to a method for compensating for dynamic skew in read/write operations of a memory device.

Random access memory (RAM) is commonly used in computing devices such as computers, mobile phones, and handheld devices, and is a volatile memory in which stored information is lost when power provided to the RAM is switched off. Double data rate random access memory (DDR RAM) is a type of RAM that is typically used in devices that perform computing applications requiring high bandwidth and low latency access.

FIG. 1A is a schematic block diagram of a conventional DDR RAM 100 that includes a DDR memory array 102, a DDR memory controller 104, and first through mth signal lines 106a, 106b, 106c, . . . to 106m (collectively referred to as signal lines 106). The signal lines 106 form a high speed DDR interface between the memory array 102 and the memory controller 104. The signal lines 106 include a strobe line 106a and data lines 106b-106m. During memory write/read operations, the data lines 106b-106m carry data signals based on a strobe signal on the strobe line 106a. Each data signal comprises a bit having a value of either ‘0’ or bit ‘1’.

FIG. 1B is a timing diagram of the strobe signal 108 and the signals 110a-110n (collectively data signals 110) carried by the signal lines 106. During a memory write operation, the strobe signal 108 and data signals 110, although generated simultaneously by the memory controller 104, may arrive at the memory array 102 at different time intervals due to varying propagation delays of the respective data lines 106. This difference in the propagation delays between the signal lines 106 can result in timing skew between the strobe signal 108 and the data signals 110. As the operating frequency of the memory device 100 increases, the timing skew widens and becomes critical. Even a short timing skew may lead to incorrect data sampling, leading to read/write errors. The timing skew thus limits the read/write speed of the DDR RAM 100.

The propagation delays may be of two types, static and dynamic. Propagation delays caused by differences in line length, temperature variations, and material variations are referred to as static propagation delays as they are independent of the data signals 110 carried by the data lines 106. The propagation delays introduced due to capacitance and inductive coupling between signal lines are referred to as dynamic propagation delays as they depend on the particular data signals 110 carried by the data lines 106. Existing skew compensation techniques compensate only for the static propagation delays. Conventional devices do not manage or compensate for dynamic skew.

Therefore, there is a need for a delay compensation system that compensates for dynamic propagation delays and skew during memory read/write operations, minimizes memory errors due to dynamic skew between the data and strobe lines, improves the speed of data read/write operations, and overcomes the above-mentioned limitations of existing DDR RAMs.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements. It is to be understood that the drawings are not to scale and have been simplified for ease of understanding the invention.

FIG. 1A is a schematic block diagram of a conventional DDR RAM;

FIG. 1B is a timing diagram of the strobe signal and the data signals on the data lines during memory write/read operations of the DDR RAM of FIG. 1A;

FIG. 2 is a schematic block diagram of a memory device including a delay compensation module in accordance with an embodiment of the present invention;

FIG. 3 is a schematic block diagram of a delay compensation logic module of the memory device of FIG. 2 in accordance with an embodiment of the present invention; and

FIG. 4 is a timing diagram illustrating a strobe signal and a plurality of data signals of the memory device of FIG. 2, in accordance with an embodiment of the present invention.

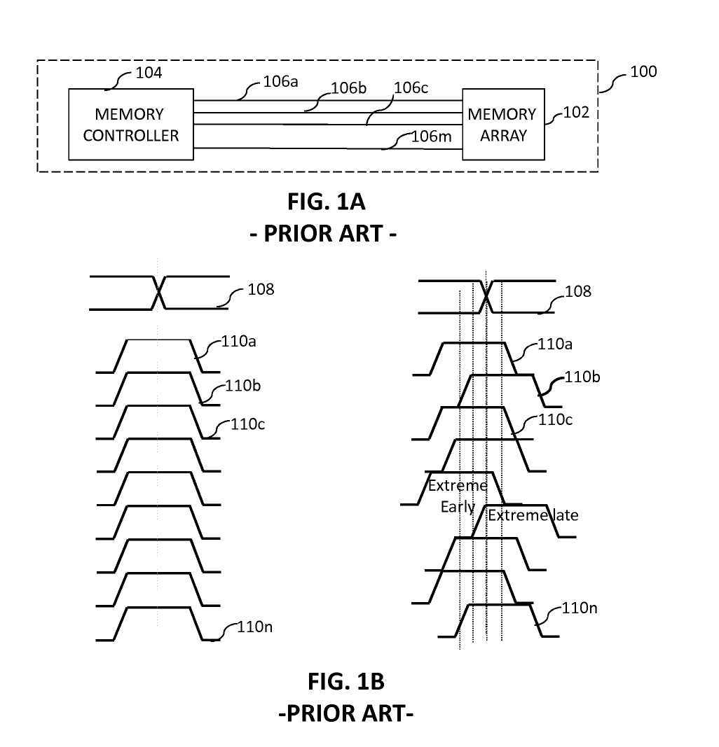

### DETAILED DESCRIPTION OF THE PRESENT INVENTION

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In an embodiment of the present invention, a memory device is provided. The memory device includes a memory array and a memory controller connected to the memory array for performing at least one of read and write operations on the memory array. A plurality of data lines connect the memory array and the memory controller, for carrying a data bit pattern for writing to and reading from the memory array during write and read operations, respectively. Each data line has a propagation delay associated therewith, wherein the propagation delay is a function of the data bit pattern carried by the plurality of data lines. A delay compensation module is connected to the memory controller for compensating the propagation delay of each data line during at least one of read and write operations. The delay compensation module comprises a delay line that receives a clock signal and includes a plurality of serially-connected delay elements for generating a plurality of delayed clock signals, and a plurality of taps located between the serially connected delay elements for providing the plurality of delayed clock signals. The delay compensation module further includes a look-up table that stores a mapping between a plurality of predefined data bit patterns, corresponding propagation delays of the plurality of data lines and tap numbers of corresponding delayed clock signals. The delay compensation module further includes a plurality of delay compensation logic modules corresponding to the plurality of data lines, wherein each delay compensation logic module receives a data bit pattern carried by the plurality of data lines, selects a tap number of the delay line based on the data bit pattern and the look-up table, and delays a bit carried by corresponding data line, based on a delayed clock signal corresponding to the selected tap number.

In another embodiment of the present invention, a memory device is provided. The memory device comprises a memory array and a memory controller connected to the memory array for performing at least one of read and write operations on the memory array. A plurality of data lines connect the memory array and the memory controller and carry a data bit pattern for writing to and reading from the memory array during write and read operations, respectively. Each data line has a propagation delay associated therewith, and the propagation delay is a function of the data bit pattern carried by the plurality of data lines. A delay compensation module is connected to the memory controller for compensating the propagation delay of each data line during at least one of read and write operations. The delay compensation module comprises a delay line, a look-up table and a plurality of delay compensation logic modules corresponding to the plurality of delay lines. The delay line receives a clock signal and includes a plurality of serially-connected delay elements for generating a plurality of delayed clock signals, and a plurality of taps located between the serially connected delay elements for providing the plurality of delayed clock signals. The look-up table stores a mapping between a plurality of predefined data bit patterns, corresponding propagation delays of the plurality of data lines and tap numbers of corresponding delayed clock signals. Each delay compensation logic module comprises a processing module, a clock multiplexer, and a flip-flop. The processing module is connected to the look-up table for receiving a data bit pattern carried by the plurality of data lines, and selecting a tap number of the delay line based on the data bit pattern and the look-up table. The clock multiplexer has a plurality of input terminals connected to corresponding plurality of taps of the delay line, a select terminal connected to an output terminal of the processing module for receiving the selected tap number by way of an output signal, and an output terminal for generating a delayed clock signal corresponding to the selected tap number. The flip-flop has an input terminal for receiving a data bit carried by a data line corresponding to the delay compensation logic module, a clock terminal connected to the output terminal of the clock multiplexer for receiving the delayed clock signal, and an output terminal for generating a delayed data bit.

Various embodiments of the present invention provide a memory device that includes a memory array, a memory controller, a plurality of data lines connecting the memory array and the memory controller, and a delay compensation module. The delay compensation module includes a delay line that provides a plurality of delayed clock signals, a look-up table (LUT) that stores a mapping between a plurality of predefined data bit patterns, and corresponding propagation delays for each data line, and a plurality of delay compensation logic modules corresponding to the plurality of data lines. A delay compensation logic module for a data line receives a data bit pattern carried by the plurality of data lines, selects a propagation delay of the data line based on the data bit pattern from the LUT, and delays a bit carried by corresponding data line, based on a delayed clock signal corresponding to the propagation delay. In this manner, each bit of the data bit pattern is delayed by corresponding delay compensation logic module before a memory read/write operation to compensate for overall dynamic skew among the data bits at end of memory read/write operation. The delay compensation module adjusts the timing of bits of each data bit pattern during memory read/write operations to minimize dynamic skew, reduces memory errors, and maximizes read/write speeds therein.

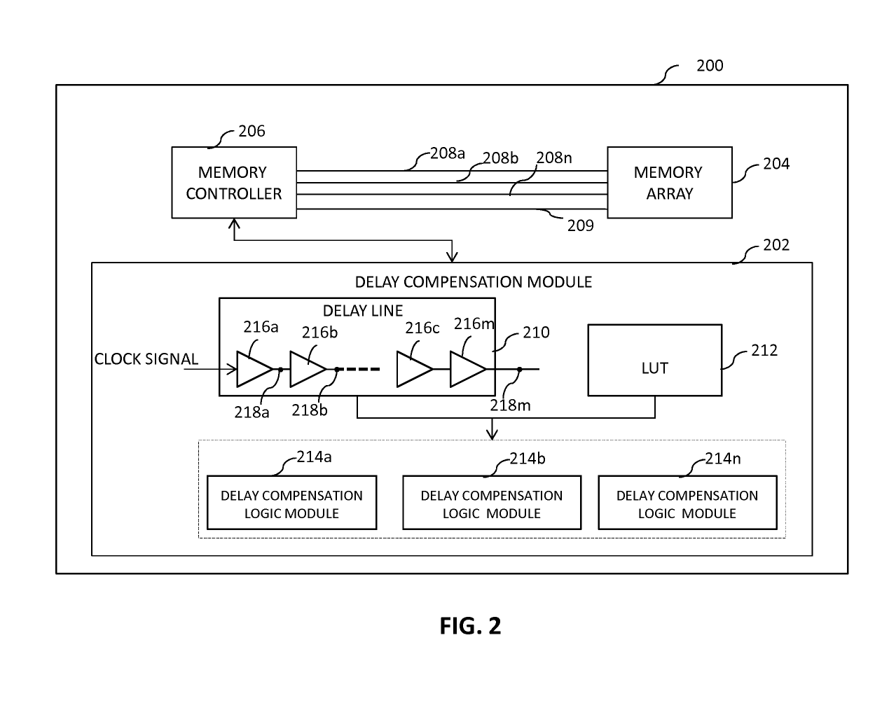

Referring now to FIG. 2, a schematic block diagram of a memory device 200 that includes a delay compensation module 202 in accordance with an embodiment of the present invention is shown. The memory device 200 includes a memory array 204 and a memory controller 206. Examples of the memory array 204 include a DDR RAM and DDR, synchronous-dynamic RAM (DDR SDRAM). The memory controller 206 may be a DDR controller that performs read and write operations on the memory array 204.

The memory controller 206 is connected to the memory array 204 by way of first through nth data lines 208a-208n (collectively referred to as data lines 208) and a strobe line 209. In one embodiment, the data lines 208 and the strobe line 209 form a high speed DDR interface between the memory controller 206 and the memory array 204. Each data line 208 carries a data bit to be written to or that has been read from the memory array 204 during memory write and read operations, respectively, based on a strobe signal on the strobe line 209. In one embodiment, the strobe signal defines a sampling period for the signals on the data lines 208, and may also be used to validate data on the data lines 208. The set of data bits carried by the data lines 208 is referred to as a data bit pattern, where the number of bits of the data bit pattern corresponds to the number of data lines 208. An example of an 8-bit pattern is 11001100, which corresponds to eight data lines 208.

For n data lines 208, each data line 208 has n−1 adjacent data lines. A data line, for example, the second data line 208b has an even state with respect to the first data line 208a when the data bits carried by the first and second data lines 208a and 208b are the same (i.e., either both ‘0’ or both ‘1’). On the other hand, the second data line 208b has an odd state with respect to the first data line 208a, when the data bits carried by the first and second data lines 208a and 208b are not the same, and the second data line 208b has a standby state when the second data line 208b is not carrying a data bit. For the first data line 208a, the even state of the adjacent second data line 208b is represented by 1, the odd state is represented by −1 and the standby state is represented by 0.

For the first data line 208a, the states of the second to nth data lines 208b-208n are collectively represented by a neighbor state Y. For example, for the first, second and third data lines 208a, 208b and 208c, if the first and third data lines 208a and 208c have odd and even states with respect to the second data line 208b, then a neighbor state Y of the second data line 208b is a set that includes odd state ‘−1’ of the first data line 208a and even state ‘1’ of the third data line 208c, and is represented by Y={−1,0, 1}.

Further, each data line 208 has a dynamic propagation delay associated therewith, which is a function of the data bits carried by the data lines 208. For example, the dynamic propagation delay of the second data line 208b is determined based on the self-inductance and self-capacitance of the second data line 208b and the mutual inductance and mutual capacitance of the first and third data lines 208a and 208c, which in turn are determined based on the neighbor state Y of the second data line 208b.

The dynamic propagation delay D[i,Y] of an i^{th} data line 208 for a neighbor state Y is determined based on the equation (1) below:

D[i, γ]=\sqrt{Lₛ·Cₛ}−\sqrt{(Lₛ+Lₘₛ)·(Cₛ−Cₘₛ)} (1)

where,
Lₛ=Self-inductance of the i^{th} data line 208, Cₛ=Self-capacitance of the i^{th} data line 208, Lₘₛ=Effective mutual inductance of the i^{th} data line 208 and adjacent data lines 208, and
Cₘₛ=Effective mutual capacitance of the i^{th} data line 208 and adjacent data lines 208.

The effective mutual inductance Lₘₛ and capacitance Cₘₛ is determined using the equations below:

$${L}_{m s} [ i ] = {\sum }_{x = - a}^{a} {L}_{m} [ i , i + x ] \cdot t [ x ] \\ {C}_{m s} [ i ] = {\sum }_{x = - a}^{a} {C}_{m} [ i , i + x ] \cdot t [ x ] \qquad ( 2 )$$

### Where,

Lₘ[i,k]=mutual inductance between i^{th} and k^{th} data lines 208,
Cₘ[i,k]=mutual capacitance between i^{th} and k^{th} data lines 208,
a=Number of adjacent data lines to be included in the delay calculations. For example, when i=2 and a=2, then (i−a)^{th} to (i+a)^{th} adjacent data lines are included in the delay calculations. For the i^{th} data line 208, the value of ‘a’ is determined based on adjacent data line(s) at which mutual coupling diminishes considerably.
t[x]=state (even, odd or standby) of the i+x^{th} data line with respect to the i^{th} data line, t[x] has a value −1, if the i+x^{th} line is in odd state, has a value +1 if the i+x^{th} line is in even state, and has a value 0 for x=0, and
Y=neighbor state of the i^{th} data line corresponding to tuple {t[−a], t[−a+1] . . . t[a−1], t[a]} for all legal values of the tuple.

The delay compensation module 202 is connected to the memory controller 206 for compensating for the dynamic propagation delays of each data line 208 before a memory read/write operation is executed to compensate for the overall dynamic skew of the data lines 208 at an end of the memory read/write operation. The delay compensation module 202 includes a delay line 210, a look-up table (LUT) 212, and first through nth delay compensation logic modules 214a-214n (collectively referred to as delay compensation logic modules 214) corresponding to the data lines 208a-208n respectively.

The LUT 212 stores a mapping between predefined data bit patterns that the data lines 208 may carry, and corresponding dynamic propagation delays of each data line 208. The total number of predefined data bit patterns is based on the number of data lines 208. For example, when the number of data lines 208 is eight, the number of predefined data bit patterns is equal to 2⁸. Each data line 208 has a neighbor state Y corresponding to a predefined bit pattern. A dynamic propagation delay D[i,Y] of an i^{th} data line 208 for a neighbor state Y₁ is determined using the equations (1) and (2). Similarly, the dynamic propagation delays of the i^{th} data line 208 for all possible neighbor states Y2, Y3, till Yz are determined and stored in the LUT 212. Thus, the LUT 212 stores the dynamic propagation delays for all values of i (1≦i≦n), for all possible corresponding neighbor states.

The delay line 210 receives a clock signal from a clock source (not shown) of the memory device 200 and includes first through m^{th} serially-connected delay elements 216a-216m (collectively referred to as delay elements 216) for generating a plurality of delayed clock signals at corresponding first through m^{th} taps 218a-218m (collectively referred to as taps 218). A delay element 216 may comprise, for example, a flip-flop or a latch.

For each data line 208, the LUT 212 stores a mapping between a plurality of neighbor states, and corresponding tap numbers of the delay line 210. For example, the LUT 212 may store the tap number ‘2’ corresponding to a neighbor state Y2={1,1,0,−1,−1} of the third data line 208c. This implies that the delayed clock signal provided by the second tap 218b may be used to adjust the timing of the data bit of the third data line 208c to compensate for the propagation delay corresponding to the neighbor state Y2.

TABLE I

| Third data line (i = 2) | | | Fourth data line (i = 3) | | |
|---|---|---|---|---|---|
| State | | | State | | |
| Name | Neighbor state | Tap No | Name | Neighbor State | Tap No |
| Y1 | {0, 0, 0, 0, 0} | 3 | Y1 | {0, 0, 0, 0, 0} | 3 |
| Y12 | {0, 0, 0, 0, −1} | 5 | Y2 | {1, 1, 0, −1, −1} | 2 |
| Y7 | {0, 0, 0, −1, 1} | 3 | Y9 | {0, 0, 0, −1, −1} | 7 |
| Y6 | {0, 1, 0, −1, −1} | 6 | Y15 | {0, −1, 0, 1, −1} | 5 |
| Y2 | {1, 0, 0, −1, −1} | 2 | Y3 | {1, 1, 0, 1, −1} | 2 |
| Y14 | {1, 1, 0, 0, 0} | 1 | Y19 | {0, 1, 0, 1, 0} | 4 |

Table I illustrates an exemplary LUT 212 in accordance with an embodiment of the present invention. The LUT 212 stores a plurality of pre-defined neighbor states and corresponding tap numbers for each data line 208. For example, for the third data line 208c (i=2), the value of a is set as 2, and one or more neighbor states of the third data line 208c, and corresponding adjacent first, second, fourth and fifth data lines 208a, 208b, 208d and 208e are determined. Similarly, for the fourth data line 208d (i=3), the value of a is set as 2, and one or more neighbor states of the fourth data line 208d and corresponding adjacent second, third, fifth and sixth data lines 208b, 208c, 208e and 208f are determined. Although neighbor states and corresponding tap numbers of third and fourth data lines 208c and 208d are shown, it will be apparent to those skilled in the art that the LUT 212 may include neighbor states and corresponding tap numbers for all the data lines 208.

The delay compensation logic modules 214 use the delay line 210 and the LUT 212 to adjust the timing of the data bits on the corresponding data lines 208 before the start of a memory read/write operation and reduce the dynamic skew among the data lines 208 at the end of the memory read/write operation. For example, the first delay compensation logic module 214a receives a data bit pattern carried by the data lines 208, determines the neighbor state of the first data line 208a from the data bit pattern, and determines a tap number of the delay line 210 based on the neighbor state from the LUT 212. Thereafter, the first delay compensation logic module 214a delays the data bit carried by the first data line 208a based on a delayed clock signal corresponding to the selected tap number. Similarly, the data bits carried by each data line 208 may be delayed by corresponding delay compensation logic modules 214 to minimize the difference in propagation delays among the data lines 208.

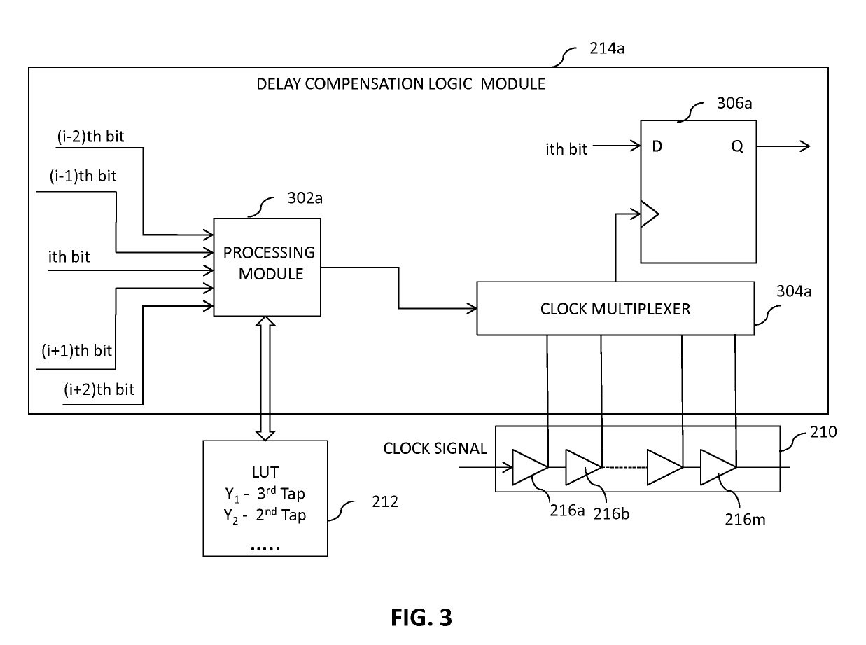

Referring now to FIG. 3, a schematic block diagram of the first delay compensation logic module 214a in accordance with an embodiment of the present invention is shown. The first delay compensation logic module 214a adjusts the timing of a data bit on the first data line 208a and includes a processing module 302a, a clock multiplexer 304a, and a flip-flop 306a.

The processing module 302a receives the data bit pattern (set of i^{th}, i+1^{th}, i+2^{th}, i−1^{th}, and i−2^{th} bits) carried by the data lines 208, and determines a neighbor state of the i^{th} bit, (i.e., the first data bit when i=0). The processing module 302a then determines a tap number corresponding to the neighbor state from the LUT 212 and provides the selected tap number to the clock multiplexer 304a by way of an output signal.

The clock multiplexer 304b has a plurality of input terminals connected to corresponding taps 218 of the delay line 210, a select terminal connected the processing module 302a for receiving the selected tap number, and an output terminal for generating a delayed clock signal corresponding to the selected tap number.

The flip-flop 306a may be, for example, a D flip-flop that has an input terminal (D terminal) that receives the i^{th} data bit of the data bit pattern, a clock terminal connected to the output terminal of the clock multiplexer 304a for receiving the delayed clock signal, and an output terminal (Q terminal) for providing a delayed i^{th} data bit based on the delayed clock signal. The i^{th} data bit is delayed before start of a memory read/write operation to compensate for corresponding dynamic propagation delay at the end of the memory read/write operation.

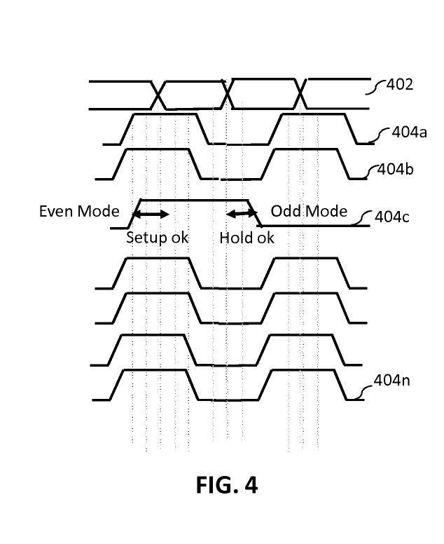

FIG. 4 is a timing diagram illustrating a strobe signal 402 carried by the strobe line 209, and first through n^{th} data signals 404a-404n (collectively referred to as data signals 404) carried by the data lines 208 in accordance with an embodiment of the present invention. The data signals 404 carry three consecutive data bit patterns, and therefore each data signal has three consecutive data bits. The third data line 208c is in an even state with respect to the first and second data lines 208a and 208b when it carries the first bit, and the third data line 208c is in an odd state with respect to the first and second data lines 208a and 208b when it carries the second bit.

The delay compensation module 202 adjusts the timing of the third data signal 404c, both during even and odd states, before a memory read/write operation to compensate for the corresponding dynamic propagation delay at the end of memory read/write operation. The delay compensation module 202 adjusts the timing of the third data signal 404c keeping in view the setup and hold time requirements of the data signal 404c. Similarly, the delay compensation module 202 adjusts the timing of the remaining data signals 404a-404n to reduce dynamic skew between the strobe signal 402 and the data signals 404, and increase speed of data read/write operations therein.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

1. A memory device, comprising:
a memory array;
a memory controller, connected to the memory array, that performs at least one of read and write operations on the memory array;
a plurality of data lines, connecting the memory array and the memory controller, for carrying a data bit pattern for writing to and reading from the memory array during write and read operations, respectively, and wherein each data line has a propagation delay associated therewith, and wherein the propagation delay is a function of said data bit pattern; and
a delay compensation module, connected to the memory controller, that compensates for the propagation delay of each data line during at least one of the read and write operations, wherein the delay compensation module comprises:
a delay line that receives a clock signal and includes a plurality of serially-connected delay elements for generating a plurality of delayed clock signals, and a plurality of taps located between the serially connected delay elements for providing the plurality of delayed clock signals;
a look-up table that stores a mapping between a plurality of predefined data bit patterns, corresponding propagation delays of the plurality of data lines, and tap numbers of corresponding delayed clock signals; and
a plurality of delay compensation logic modules corresponding to the plurality of data lines, wherein each delay compensation logic module receives one of said data bit patterns, selects a tap number for the delay line from the look-up table based on the data bit pattern, and delays a bit carried by the corresponding data line based on a delayed clock signal corresponding to the selected tap number.

2. The memory device of claim 1, wherein each delay compensation logic module comprises:
a processing module, connected to the look-up table, that receives said data bit pattern and selects the tap number for the delay line from the look-up table;
a clock multiplexer that has a plurality of input terminals connected to the taps of the delay line, a select terminal connected to an output terminal of the processing module for receiving the selected tap number, and an output terminal for generating a delayed clock signal corresponding to the selected tap number; and
a flip-flop that has an input terminal for receiving a data bit of said data bit pattern carried by a data line corresponding to the delay compensation logic module, a clock terminal connected to the output terminal of the clock multiplexer for receiving the delayed clock signal, and an output terminal for providing a delayed data bit.

3. The memory device of claim 1, wherein for each data line, the look-up table stores a plurality of neighbor states, wherein a neighbor state corresponds to a predefined data bit pattern carried by a plurality of adjacent data lines.

4. The memory device of claim 3, wherein for each data line, an adjacent data line is in an even state when said data bits carried by the data line and the adjacent data line have a same value.

5. The memory device of claim 4, wherein for each data line, an adjacent data line is in an odd state when said data bits carried by the data line and the adjacent data line do not have a same value.

6. The memory device of claim 5, wherein for each data line, an adjacent data line is in a standby state when the adjacent data line is not carrying a data bit.

7. The memory device of claim 6, wherein the odd and even states of the adjacent data line are represented by the value 1, and the standby state is represented by the value 0.

8. The memory device of claim 1, wherein the propagation delay for each data line is determined based on self-inductance and self-capacitance of the data line and mutual inductance and mutual capacitance of adjacent data lines.

9. A memory device, comprising:
a memory array;
a memory controller, connected to the memory array, that performs at least one of read and write operations on the memory array;
a plurality of data lines, connecting the memory array and the memory controller, for carrying a data bit pattern for writing to and reading from the memory array during write and read operations, respectively, and wherein each data line has a propagation delay associated therewith, and wherein the propagation delay is a function of the data bit pattern carried by the plurality of data lines; and
a delay compensation module, connected to the memory controller, that compensates the propagation delay of each data line during at least one of read and write operations, wherein the delay compensation module comprises:
a delay line that receives a clock signal and includes a plurality of serially-connected delay elements for generating a plurality of delayed clock signals, and a plurality of taps located between the serially connected delay elements for providing the plurality of delayed clock signals;
a look-up table that stores a mapping between a plurality of predefined data bit patterns, corresponding propagation delays of the plurality of data lines, and tap numbers of corresponding delayed clock signals; and
a plurality of delay compensation logic modules corresponding to the plurality of data lines, wherein each delay compensation logic module comprises:
a processing module, connected to the look-up table, that receives a data bit pattern carried by the plurality of data lines, and selects a tap number for the delay line from the look-up table based on the data bit pattern;
a clock multiplexer, that has a plurality of input terminals connected to a corresponding plurality of the taps of the delay line, a select terminal connected to an output terminal of the processing module for receiving the selected tap number, and an output terminal for generating a delayed clock signal corresponding to the selected tap number; and
a flip-flop, that has an input terminal for receiving a data bit carried by a data line corresponding to the delay compensation logic module, a clock terminal connected to the output terminal of the clock multiplexer for receiving the delayed clock signal, and an output terminal for generating a delayed data bit.

10. The memory device of claim 9, wherein the look-up table stores a plurality of neighbor states for each data line, wherein a neighbor state corresponds to a predefined data bit pattern carried by a plurality of adjacent data lines.

11. The memory device of claim 10, wherein for each data line, an adjacent data line is in an even state when data bits carried by the data line and the adjacent data line are the same.

12. The memory device of claim 11, wherein for each data line, an adjacent data line is in an odd state when data bits carried by the data line and the adjacent data line are not the same.

13. The memory device of claim 12, wherein for each data line, an adjacent data line is in a standby state when the adjacent data line is not carrying a data bit.

14. The memory device of claim 13, wherein the odd and even states of the adjacent data line is represented by a value 1 and the standby state is represented by a value 0.

15. The memory device of claim 9, wherein for each data line, the propagation delay is determined based on self-inductance and self-capacitance of the data line and mutual inductance and mutual capacitance of adjacent data lines.
